(19) United States
(12) Patent Application Publication
(10) Pub. No.: US 2012/0081147 A1
(43) Pub. Date: Apr. 5, 2012

(54) APPARATUS AND METHOD FOR CONTROLLING SIGNAL DISTRIBUTION IN A SEMICONDUCTOR INTEGRATED CIRCUIT

(75) Inventor: NEIL PRICE, Bristol (GB)

(73) Assignee: PANASONIC CORPORATION, Osaka (JP)

(21) Appl. No.: 12/895,388

(22) Filed: Sep. 30, 2010

(51) Int. Cl. H03K 19/177

(52) U.S. Cl. 326/39

(57) ABSTRACT

A programmable logic device includes a plurality of first type repeating units, each of which includes interconnecting lines and a logic block comprising logic circuits. The plurality of first type repeating units includes first, second and third repeating units. The first repeating unit comprises a first clock line for propagating a clock signal with a first delay input from the third repeating unit and output to the second repeating unit.

### TECHNICAL FIELD

The technical field relates to a semiconductor integrated circuit, and more particularly to signal distribution techniques for use in programmable logic devices (PLDs) such as field programmable logic arrays (FPGAs), application-specific integrated circuits (ASICs), or other semiconductor integrated circuits.

### BACKGROUND

Distribution of clocks, data and other signals is an important aspect of semiconductor integrated circuit design. Especially, it is preferable to manipulate clock delays to optimize the performance of the semiconductor integrated circuit.

FIG. 24 shows a portion of an electronic circuit 300 which includes a single flip-flop (FF) 302 and a corresponding delay selection unit 304 disclosed in U.S. Pat. No. 6,873,187, hereinafter Patent Reference 1. The single FF 302 may be viewed as one of many embedded memory elements of an FPGA, ASIC or other electronic circuit. The corresponding delay selection unit 304 in this example includes four different delay lines 306-1, 306-2, 306-3 and 306-4, a particular one of which is selected by multiplexer 308 for use in propagating the clock signal to the clock signal input of FF 302 via clock signal line 310. Each of the paths 306-1, 306-2, 306-3 and 306-4 provides a different delay, with these delays being denoted D.sub.1, D.sub.2, D.sub.3 and D.sub.4, respectively, in order of increasing delay.

Patent Reference 1: U.S. Pat. No. 6,873,187

### SUMMARY

However, the Patent Reference 1 doesn't disclose particular configuration of the delay selection unit 304. It is desired to provide area conserving configuration of such a unit.

To achieve the above object, as well as other concern, a programmable logic device includes a plurality of first type repeating units, each of which includes interconnecting lines and a logic block comprising logic circuits, wherein the plurality of first type repeating units includes first, second and third repeating units, wherein the first repeating unit comprises a first clock line for propagating a clock signal with a first delay input from the third repeating unit and output to the second repeating unit.

The first repeating unit can be adjacent to the second repeating unit and the third repeating unit. The first repeating unit can further include a second clock line for propagating the clock signal with a second delay, input from the second repeating unit and output to the third repeating unit, preferably.

The first repeating unit can further include a multiplexer, the first clock line and the second clock line are connected to the multiplexer, and the multiplexer outputs one of the clock signal with the first delay and the clock signal with the second delay to a logic block included in the first repeating unit, preferably.

The first repeating unit, the second repeating unit and the third repeating unit can preferably be in a same column. The first clock line and the second clock line can preferably be substantially parallel.

The first repeating unit preferably further includes a second clock line for propagating the clock signal with a second delay, input from a fourth repeating unit included in the plurality of first type repeating units and output to a fifth repeating unit included in the plurality of first type repeating units.

Preferably, the first repeating unit, the second repeating unit and the third repeating unit are in a same column, and the first repeating unit, the fourth repeating unit and the fifth repeating unit are in a same row.

The first repeating unit further comprises a multiplexer, the first clock line and the second clock line are connected to the multiplexer, and the multiplexer outputs one of the clock signal with the first delay and the clock signal with the second delay to a logic block included in the first repeating unit, preferably.

The programmable logic device further comprises a plurality of second type repeating units, each of which includes interconnecting lines and a logic block comprising logic circuits, wherein a fourth repeating unit, included in the plurality of second type repeating units, comprises a second clock line for propagating a clock signal with a second delay, input from a fifth repeating unit included in the plurality of second type repeating units and output to a sixth repeating unit included in the plurality of second type repeating units, the first repeating unit, the second repeating unit and the third repeating unit are in a same column, the fourth repeating unit and the fifth repeating unit are in a same column, and the fourth repeating unit and the sixth repeating unit are in a same row, preferably.

A programmable logic device can include: a plurality of repeating units; and an external clock line for providing a clock signal to one or more of the plurality of repeating units, wherein each of the plurality of repeating units includes: a logic block comprising logic circuits; an internal clock line for receiving the clock signal from either the external clock line or an adjacent one of the plurality of repeating units and propagating the clock signal to another adjacent one of the plurality of repeating units or the external clock line.

Each of the plurality of repeating units further includes: a plurality of the internal clock lines, each for respectively receiving the clock signal from either the external clock line or a different adjacent one of the plurality of repeating units and propagating the clock signal to another different adjacent one of the plurality of repeating units or the external clock line; and a selection unit coupled to the plurality of internal clock lines and the logic block for selecting one of the plurality of internal clock lines, preferably.

Each of the plurality of the internal clock lines can propagate the clock signal with a different delay, preferably.

The plurality of repeating units can be arranged in a matrix configuration, wherein the one or more of the plurality of repeating units receiving the clock signal from the external clock line are disposed in a column or row of the matrix configuration, preferably.

The plurality of repeating units can be arranged in a matrix configuration, wherein the external clock line includes a first portion for sending the clock signal to a first group of the one or more of the plurality of repeating units disposed in a first column or row of the matrix configuration and a second portion for returning the clock signal to each of a second group of the one or more of the plurality of repeating units disposed in a second column or row of the matrix configuration.

By the above-stated structure, area of a chip where the semiconductor integrated circuit is fabricated is conserved and clock with several delays can be provided to a tile.

### BRIEF DESCRIPTION OF DRAWINGS

FIG. 1 is a diagram of simplified PLD architecture of embodiment 1.

FIG. 2 is a simplified diagram of a tile.

FIG. 3 is a schematic diagram of clock propagation of the PLD.

FIG. 4 is a simplified diagram of a tile.

FIG. 5 is a table of delays of clock signal.

FIG. 6 is simplified diagram of a tile.

FIG. 7 is a diagram of simplified PLD architecture of embodiment 2.

FIG. 8 is a schematic diagram of clock propagation of the PLD.

FIG. 9 is simplified diagram of a tile.

FIG. 10 is a table of delays of clock signal.

FIG. 11 is a diagram of simplified PLD architecture of embodiment 3.

FIG. 12 is a schematic diagram of clock propagation of the PLD.

FIG. 13 is a simplified diagram of a tile.

FIG. 14 is a table of delays of clock signal.

FIG. 15 is a simplified diagram of a tile.

FIG. 16 is a diagram of simplified PLD architecture of embodiment 4.

FIG. 17 is a schematic diagram of clock propagation of the PLD.

FIG. 18 is a simplified diagram of a tile.

FIG. 19 is a table of delays of clock signal.

FIG. 20 is a simplified diagram of a tile.

FIG. 21 is a diagram of simplified PLD architecture of embodiment 5.

FIG. 22 is a schematic diagram of clock propagation of the PLD.

FIG. 23 is a table of delays of clock signal.

### DESCRIPTION OF EMBODIMENTS

### Embodiment 1

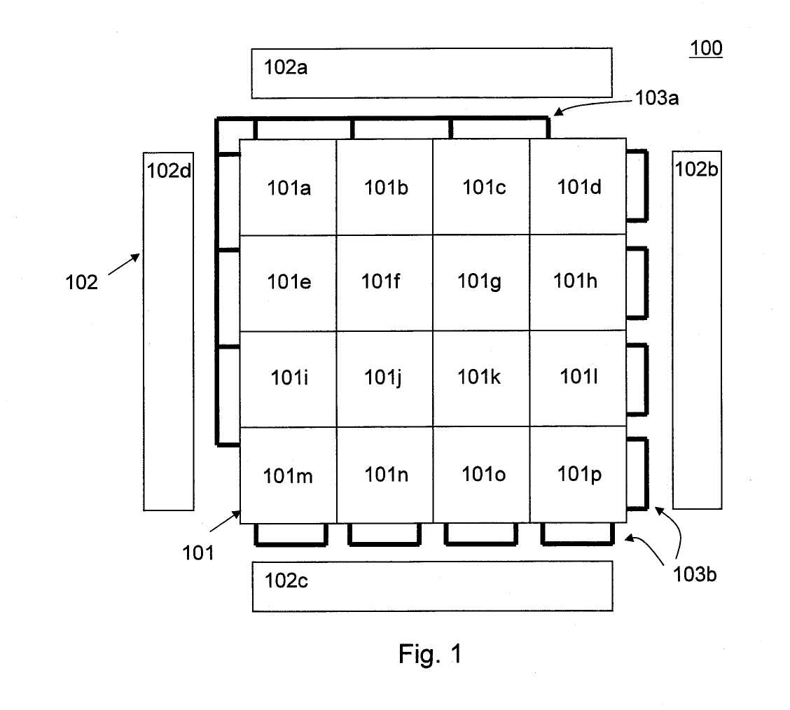

FIG. 1 illustrates a simplified PLD architecture 100 of embodiment 1 in plain view. The PLD 100 includes an array of tiles 101a-101p, programmable input/output (I/O) blocks 102a-102d, and external clock lines 103a and 103b. Some of the tiles 101a-101p and I/O blocks 102a-102d are connected by a number of connecting lines (not shown in the FIG. 1). The external clock line 103a is connected to the tiles 101a, 101b, 101c, 101e, 101i and 101m. The external clock lines 103b are connected to two ports of tiles 101d, 101h, 101l, 101p, 101m, 101n, 101o and 101p, respectively. A clock signal propagates in the external clock lines 103a and 103b. Note that in this document “external” means “outside of the tiles” in plain view. Conventional PLDs include a clock tree, such as the balanced tree (e.g. the H clock tree), and have external clock lines between all tiles, but the PLD of the embodiment 1 doesn't have such external clock lines between tiles which waste space of the PLD. Once the clock signal is provided into the tiles 101, the clock signal propagates in internal clock lines of the tiles 101, which will be explained. Note that in this document “internal” means “inside of the tiles” in plain view.

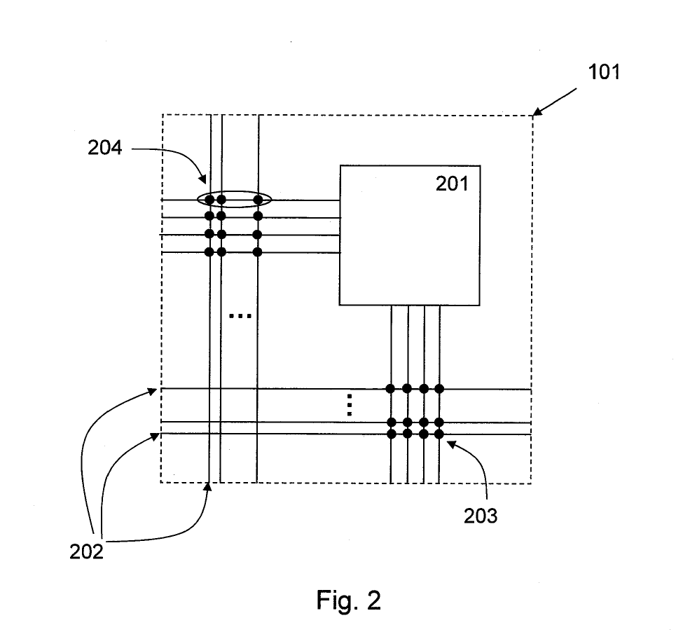

FIG. 2 shows simplified illustration of a tile 101, which is one of the tiles 101a-101p, other than elements related to clock propagation. The tiles 101a-101p have similar structure. In other words, the tile 101 is a repeating unit of the PLD 100. The tile 101 includes a logic block 201 and a number of interconnecting lines 202. The logic block 201 includes logic circuits and at least one registers for holding data. The interconnecting lines are interconnected by programmable interconnect points 203 (PIPs, shown as small dots in FIG. 2). PIPs are often coupled into groups (e.g. group 204) that implement multiplexer circuits selecting one of several interconnecting lines to provide a signal to a destination interconnecting line or the logic block 201.

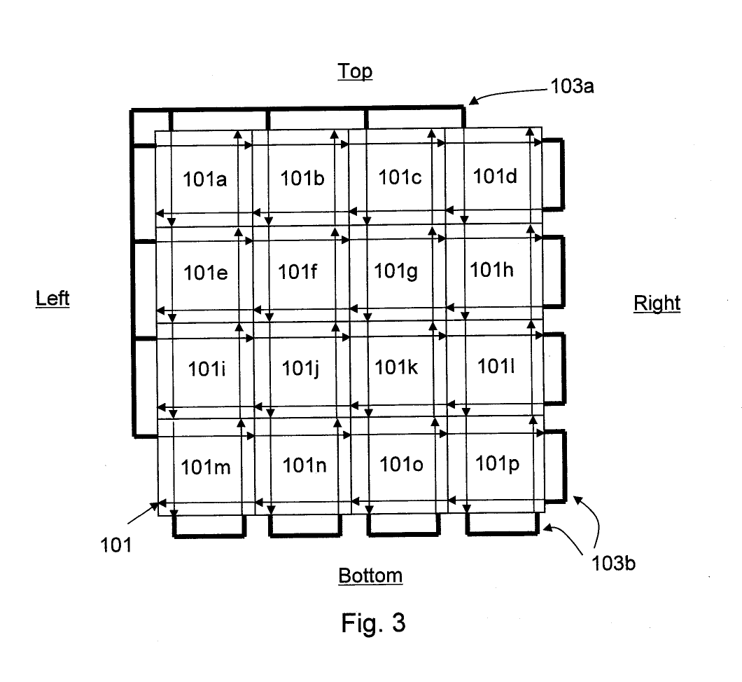

FIG. 3 shows schematic diagram of clock propagation of the PLD 100. The clock signal is provided via the external clock line 103a from a source of the clock signal (not shown) to the tiles 101a, 101b, 101c, 101d, 101e, 101i and 101m, almost at the same time. In the embodiment 1, the external clock line 103a is adjusted so that the clock signal outside of the tiles arrives at every tile at substantially the same time. Possible ways to adjust the arrival time of the clock signal are, for example, to add capacitance to a particular line, to adjust length of a particular line, and so on. The clock signal propagates from top to bottom and from left to right of the array of the tiles 101a-101p. At the right edge of the tiles 101d, 101h, 101l and 101p, and at the bottom edge of the tiles 101m-101p, the clock signal once goes out of the tiles 101d, 101h, 101l, 101p, 101m, 101n, 101o and 101p and comes back into the tiles 101d, 101h, 101l, 101p, 101m, 101n, 101o and 101p, via the external clock lines 103b, respectively. The external clock lines 103b are adjusted not to delay the clock signal by, for example, making length of the external clock lines 103b sufficiently short. When the clock signal propagates from the top to the bottom, the clock signal will be called a top clock signal, when the clock signal propagates from the bottom to the top, the clock signal will be called a bottom clock signal, when the clock signal propagates from the left to the right, the clock signal will be called a left clock signal, and when the clock signal propagates from the right to the left, the clock signal will be called a right clock signal.

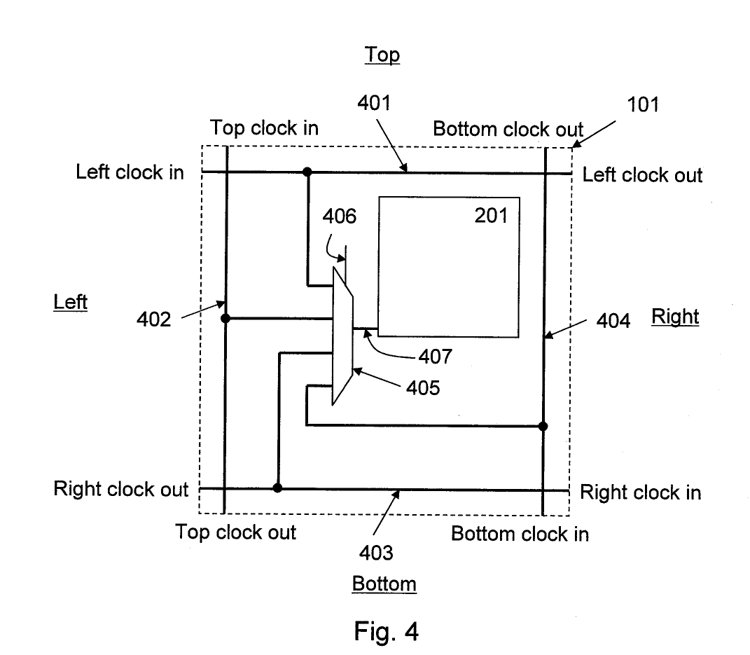

FIG. 4 shows simplified illustration of the tile 101, especially elements related to clock propagation. The tile 101 further comprises internal clock lines 401, 402, 403 and 404, a multiplexer 405, a mux control line 406, and a mux output line 407. The clock signal propagates in the internal clock lines 401, 402, 403 and 404. The internal clock line 401 is in the vicinity of top side of the tile 101, the internal clock line 402 is in the vicinity of left side of the tile 101, the internal clock line 403 is in the vicinity of bottom side of the tile 101 and the internal clock line 404 is in the vicinity of right side of the tile 101. In this embodiment 1, the internal clock line 401 and the internal clock line 403 are substantially parallel, and the internal clock line 402 and the internal clock line 404 are substantially parallel. However, placement of the internal clock lines is not limited to this arrangement. The top clock signal propagates in the internal clock line 402 in the tile 101, from a top clock in on a top edge of the tile 101 to a top clock out on a bottom edge of the tile 101. The bottom clock signal propagates in the internal clock line 404 in the tile 101, from a bottom clock in on a bottom edge of the tile 101 to a bottom clock out on a top edge of the tile 101. The left clock signal propagates in the internal clock line 401 in the tile 101, from a left clock in on a left edge of the tile 101 to a left clock out on a right edge of the tile 101. The right clock signal propagates in the internal clock line 403 in the tile 101, from a right clock in on a right edge of the tile 101 to a right clock out on a left edge of the tile 101.

The internal clock lines 401, 402, 403 and 404 are connected to input ports of the multiplexer 405. The mux control line 406 is connected to a control port of the multiplexer 405. A mux control signal is provided to the multiplexer 405 via the mux control line 406. The output port of the multiplexer 405 is connected to the mux output line 407. The multiplexer 405 selects one of the internal clock lines 401, 402, 403, and 404 according to the mux control signal of the mux control line 406, and electrically connects the selected line to the mux output line 407. Then the clock signal which propagates in the selected line propagates to the mux output line 407. The mux output line 407 is connected to the logic block 201, so the clock signal which propagates in the selected line propagates into the logic block 201 as an internal clock signal. Usually one of the internal clock lines 401, 402, 403 and 404 is selected at the time of mapping applications to the PLD by toolchains, therefore the mux control signal is usually also determined at the time of mapping applications to the PLD. The toolchains choose a suitable set of the internal clock lines for each tile by using information of timing analysis. Configuration memories store information of the mux control signal, and based on the information the mux control signal is generated in the tile 101 and provided to the multiplexer 407.

In the embodiment 1, the tile 101 includes one multiplexer 405. But the tile 101 can include a plurality of multiplexers to provide the clock signal with different delays to the logic block 201. The number of multiplexers is not limited to this arrangement.

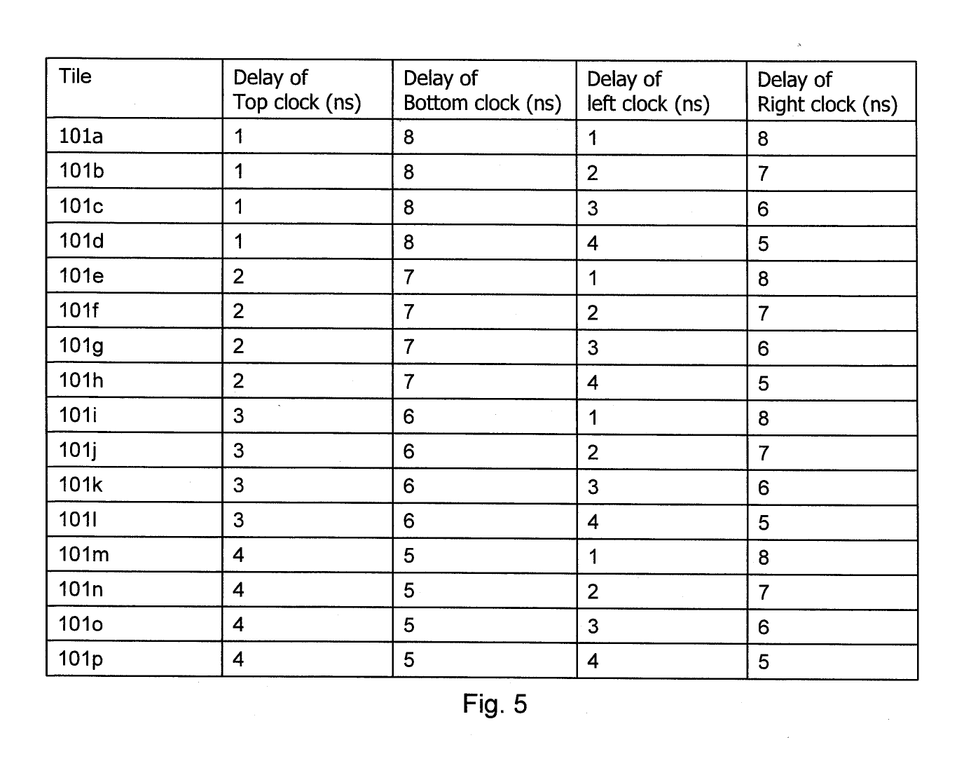

FIG. 5 shows a table of delays of the top clock signal, the bottom clock signal, the left clock signal and the right clock signal from the clock signal propagating in the external clock line 103a for each tile 101a-101p. As the internal clock distribution structure is created by putting together repeating tiles 101, the delay of the clock signal is predictable with a high degree of accuracy at each point of the array of the tiles 101. In the embodiment 1, the delay through a tile 101 is 1 ns in each internal clock line 401, 402, 403 and 404. Tiles 101 are characterized to give accurate 1 ns delays for each internal clock line 401, 402, 403 and 404. The delay can be adjusted by, for example, adding some delay elements, adjusting length of the internal clock lines, and so on. The delay of a certain tile is calculated by working out the number of tiles that the clock signal passes through and multiplying the number by the tile delay, 1 nanosecond (ns) in the embodiment 1.

For example, the delay of the top clock signal, the bottom clock signal, the left clock signal and the right clock signal of the tile 101f is calculated as follows. The top clock signal of the tile 101f passes, from the external clock line 103a to the tile 101f, the tile 101b and the tile 101f itself. In this embodiment 1 the tile itself for which the delay is calculated is included in the number of tiles that the clock signal passes through. The top clock signal of the tile 101f passes 2 tiles, so the delay of the top clock signal of the tile 101f is calculated by 2*1(ns). Therefore, the delay of the top clock signal of the tile 101f is 2 ns, as shown in the FIG. 5. The bottom clock signal of the tile 101f passes, from the external clock line 103a to the tile 101f, the tile 101b, 101f itself, 101j, 101n, 101n, 101j, and 101f itself. The bottom clock signal of the tile 101f passes 7 tiles, so the delay of the bottom clock signal of the tile 101f is calculated by 7*1(ns). Therefore, the delay of the bottom clock signal of the tile 101f is 7 ns, as shown in the FIG. 5. The left clock signal of the tile 101f passes, from the external clock line 103a to the tile 101f, the tile 101e and 101f itself. The left clock signal of the tile 101f passes 2 tiles, so the delay of the left clock signal of the tile 101f is calculated by 2*1(ns). Therefore, the delay of the left clock signal of the tile 101f is 2 ns, as shown in the FIG. 5. The right clock signal of the tile 101f passes, from the external clock line 103a to the tile 101f, the tile 101e, 101f itself, 101g, 101h, 101h, 101g and 101f itself. The right clock signal of the tile 101f passes 7 tiles, so the delay of the right clock signal of the tile 101f is calculated by 7*1(ns). Therefore, the delay of the right clock signal of the tile 101f is 7 ns, as shown in the FIG. 5. To the multiplexer 405 of the 101f, the top clock signal with the delay of 2 ns, the bottom signal with the delay of 7 ns, the left clock signal of the delay of 2 ns, and the right clock signal of the delay of 7 ns are input. The internal clock signal of the tile 101f is selected from the clock signal with 2 ns delay and the clock signal with 7 ns delay.

For example, the delay of the top clock signal, the bottom clock signal, the left clock signal and the right clock signal of the tile 101l is calculated as follows. The top clock signal of the tile 101l passes, from the external clock line 103a to the tile 101l, the tile 101d, the tile 101h and the tile 101l itself. The top clock signal of the tile 101l passes 3 tiles, so the delay of the top clock signal of the tile 101l is calculated by 3*1(ns). Therefore, the delay of the top clock signal of the tile 101l is 3 ns, as shown in the FIG. 5. The bottom clock signal of the tile 101l passes, from the external clock line 103a to the tile 101l, the tile 101d, 101h, 101l itself, 101p, 101p, and 101l itself. The bottom clock signal of the tile 101l passes 6 tiles, so the delay of the bottom clock signal of the tile 101l is calculated by 6*1(ns). Therefore, the delay of the bottom clock signal of the tile 101l is 6 ns, as shown in the FIG. 5. The left clock signal of the tile 101l passes, from the external clock line 103a to the tile 101l, the tile 101i, 101j, 101k and 101l itself. The left clock signal of the tile 101l passes 4 tiles, so the delay of the left clock signal of the tile 101l is calculated by 4*1(ns). Therefore, the delay of the left clock signal of the tile 101l is 4 ns, as shown in the FIG. 5. The right clock signal of the tile 101l passes, from the external clock line 103a to the tile 101l, the tile 101i, 101j, 101k, 101l itself and 101l itself. The right clock signal of the tile 101l passes 5 tiles, so the delay of the right clock signal of the tile 101l is calculated by 5*1(ns). Therefore, the delay of the right clock signal of the tile 101l is 5 ns, as shown in the FIG. 5. To the multiplexer 405 of the 101l, the top clock signal with the delay of 3 ns, the bottom signal with the delay of 6 ns, the left clock signal of the delay of 4 ns, and the right clock signal of the delay of 5 ns are input. The internal clock signal of the tile 101l is selected from the clock signal with 3 ns delay, the clock signal with 4 ns delay, the clock signal with 5 ns delay and the clock signal with 6 ns delay.

As described above, the PLD according to the embodiment 1 can provide clock signals with different delays to each tile 101a-101 p without additional delay elements. As the clock signal is distributed by using internal clock lines, gaps between tiles for conventional clock trees are not required. Therefore, the area of the chip on which the PLD is fabricated is much conserved.

### Modification Example of Embodiment 1

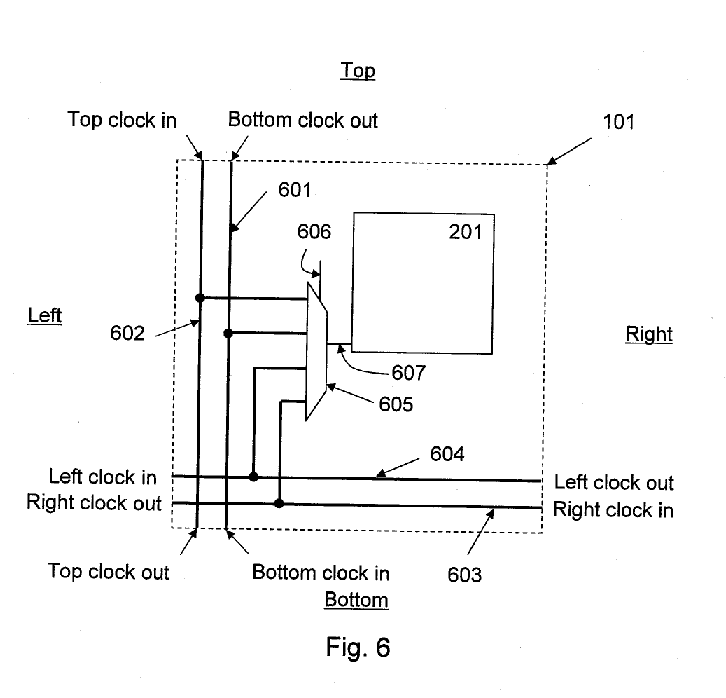

A modification of example 1 is different from the embodiment 1 in that the tile structure, especially elements related to clock propagation is as shown in FIG. 6.

FIG. 6 shows simplified illustration of the tile 101, especially elements related to clock propagation. The tile 101 comprises internal clock lines 601, 602, 603 and 604, a multiplexer 605, a mux control line 606, and a mux output line 607. The clock signal propagates in the internal clock lines 601, 602, 603 and 604. The internal clock line 601 and 602 are in the vicinity of the left side of the tile 101, and the internal clock line 603 and 604 are in the vicinity of the bottom side of the tile 101. The top clock signal propagates in the internal clock line 602 in the tile 101, from a top clock in on a top edge of the tile 101 to a top clock out on a bottom edge of the tile 101. The bottom clock signal propagates in the internal clock line 601 in the tile 101, from a bottom clock in on a bottom edge of the tile 101 to a bottom clock out on a top edge of the tile 101. The left clock signal propagates in the internal clock line 604 in the tile 101, from a left clock in on a left edge of the tile 101 to a left clock out on a right edge of the tile 101. The right clock signal propagates in the internal clock line 603 in the tile 101, from a right clock in on a right edge of the tile 101 to a right clock out on a left edge of the tile 101.

The internal clock lines 601, 602, 603 and 604 are connected to input ports of the multiplexer 605. The mux control line 606 is connected to a control port of the multiplexer 605. A mux control signal is provided to the multiplexer 605 via the mux control line 606. The output port of the multiplexer 605 is connected to the mux output line 607. The multiplexer 605 selects one of the internal clock lines 601, 602, 603, and 604 according to the mux control signal of the mux control line 606, and electrically connects the selected line to the mux output line 607. Then the clock signal which propagates in the selected line propagates to the mux output line 607. The mux output line 607 is connected to the logic block 201, so the clock signal which propagates in the selected line propagates into the logic block 201 as an internal clock signal.

The internal clock lines 601 and 602 can be placed in the vicinity of right side of the tile 101 or in the middle of the tile 101 if there is a space for them. The internal clock lines 603 and 604 can be placed in the vicinity of top side of the tile 101 or in the middle of the tile 101 if there is a space for them.

### Embodiment 2

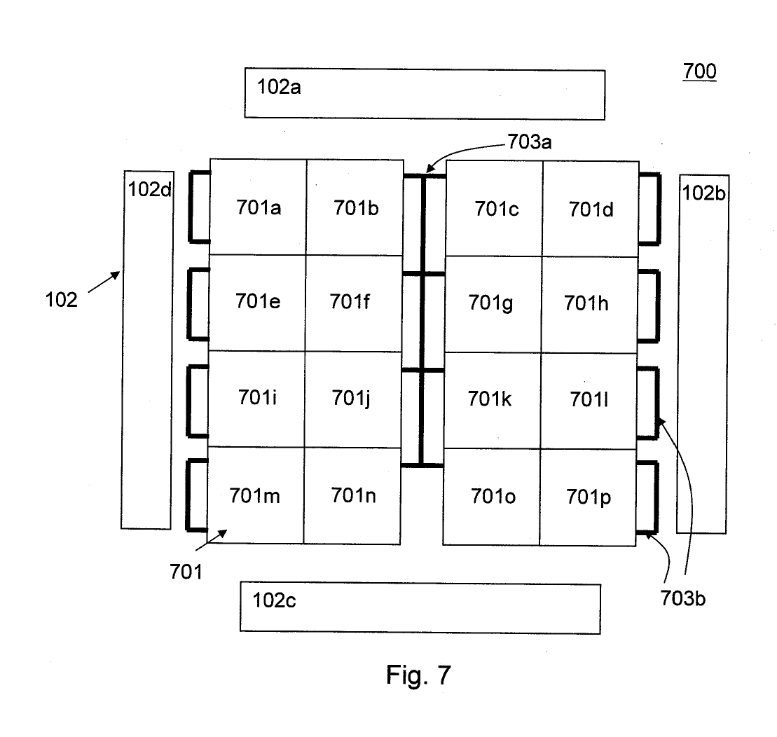

FIG. 7 illustrates simplified PLD architecture 700 of embodiment 2 in plain view. The elements which are the same as that of the PLD 100 have the same numbers as that of the PLD 100 of the embodiment 1. The PLD 700 includes an array of tiles 701a-701p, programmable I/O blocks 102a-102d, and external clock lines 703a and 703b. Some of the tiles 701a-701p and I/O blocks 102a-102d are connected by a number of connecting lines (not shown in the FIG. 7). The external clock line 703a is connected to the tiles 701b, 701c, 701f, 701g, 701j, 701k, 701n, and 701o. The external clock lines 703b are connected to two ports of tiles 701a, 701d, 701e, 701h, 701i, 701l, 701m, and 701p, respectively. A clock signal propagates in the external clock lines 703a and 703b. Conventional PLDs include a clock tree, such as the balanced tree (e.g. the H clock tree), and have external clock lines between all tiles, but the PLD of the embodiment 2 have few external clock lines between tiles which waste space of the PLD. Once the clock signal is provided into the tiles 701, the clock signal propagates in internal clock lines of the tiles 701, which will be explained. Structure of tile 701, which is one of the tiles 701a-701p, other than elements related to clock propagation is as shown in the FIG. 2.

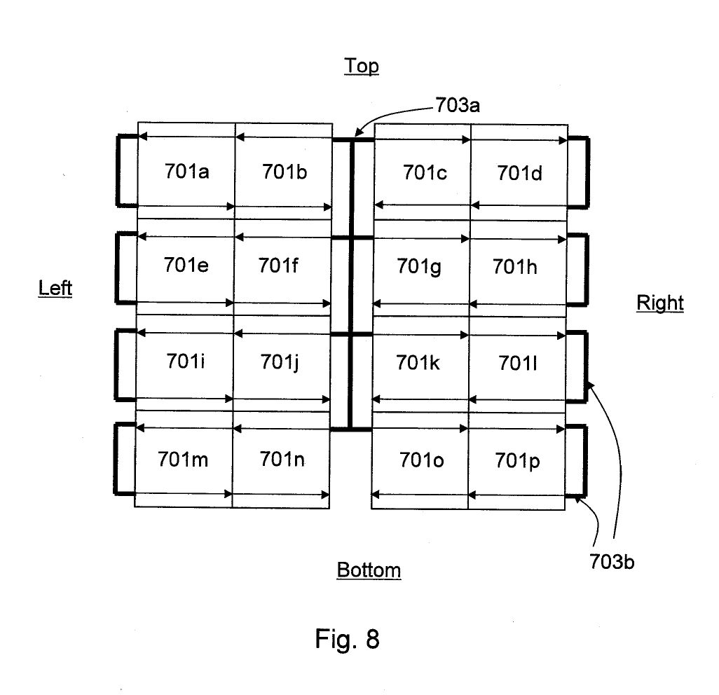

FIG. 8 shows schematic diagram of clock propagation of the PLD 700. The clock signal is provided via the external clock line 703a from a source of the clock signal (not shown) to the tiles 701b, 701c, 701f, 701g, 701j, 701k, 701n and 701o, almost at the same time. In the embodiment 2, the external clock line 703a is adjusted so that the clock signal enters the tiles at substantially the same time from outside of the tiles. Possible ways to adjust the arrival time of the clock signal are, for example, to add capacitance to a particular line, to adjust length of a particular line, and so on. The clock signal propagates from left to right of the array of the tiles 701c, 701d, 701g, 701h, 701k, 701l, 701o, and 701p. The clock signal also propagates from right to left of the array of the tiles 701a, 701b, 701e, 701f, 701i, 701j, 701m, and 701n. At the right edge of the tiles 701d, 701h, 701l and 701p, and at the left edge of the tiles 701a, 701e, 701i, and 701m, the clock signal once goes out of the tiles 701a, 701d, 701e, 701h, 701i, 701l, 701m, and 701p and comes back into the tiles 701a, 701d, 701e, 701h, 701i, 701l, 701m, and 701p, respectively, via the external clock lines 703b. The external clock lines 703b are adjusted not to delay the clock signal by, for example, making length of the external clock lines 703b sufficiently short. When the clock signal propagates from the left to the right, the clock signal will be called a left clock signal, and when the clock signal propagates from the right to the left, the clock signal will be called a right clock signal.

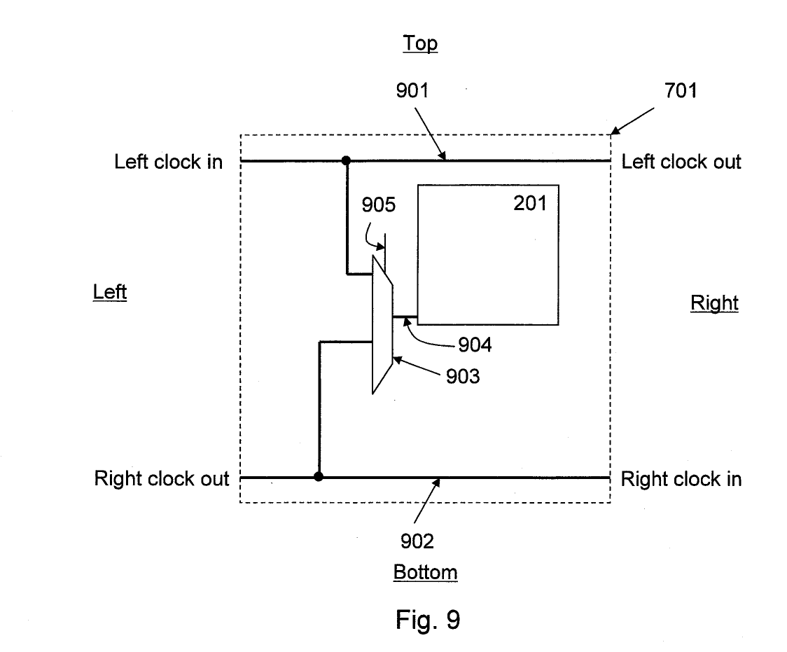

FIG. 9 shows simplified illustration of the tile 701, especially elements related to clock propagation. The tile 701 further comprises internal clock lines 901 and 902, a multiplexer 903, a mux control line 905, and a mux output line 904. The clock signal propagates in the internal clock lines 901 and 902. The internal clock line 901 is in the vicinity of top side of the tile 701, and the internal clock line 902 is in the vicinity of bottom side of the tile 701. If the space of the tile 701 is available, both of the internal clock lines 901 and 902 can be placed in the vicinity of top side of the tile 701, both of the internal clock lines 901 and 902 can be placed in the vicinity of bottom side of the tile 701, and both of the internal clock lines 901 and 902 can be placed in the middle of the tile 701. The left clock signal propagates in the internal clock line 901 in the tile 701, from a left clock in on a left edge of the tile 701 to a left clock out on a right edge of the tile 701. The right clock signal propagates in the internal clock line 902 in the tile 701, from a right clock in on a right edge of the tile 701 to a right clock out on a left edge of the tile 701.

The internal clock lines 901 and 902 are connected to input ports of the multiplexer 903. The mux control line 905 is connected to a control port of the multiplexer 903. A mux control signal is provided to the multiplexer 903 via the mux control line 905. The output port of the multiplexer 903 is connected to the mux output line 904. The multiplexer 903 selects one of the internal clock lines 901 and 902 according to the mux control signal of the mux control line 905, and electrically connects the selected line to the mux output line 904. Then the clock signal which propagates in the selected line propagates to the mux output line 904. The mux output line 904 is connected to the logic block 201, so the clock signal which propagates in the selected line propagates into the logic block 201 as an internal clock signal. Usually one of the internal clock lines 901 and 902 is selected at the time of mapping applications to the PLD, therefore the mux control signal is usually also determined at the time of mapping applications to the PLD by toolchains. The toolchains choose a suitable set of the internal clock lines for each tile by using information of timing analysis. Configuration memories store information of the mux control signal, and based on the information the mux control signal is generated in the tile 701 and provided to the multiplexer 903.

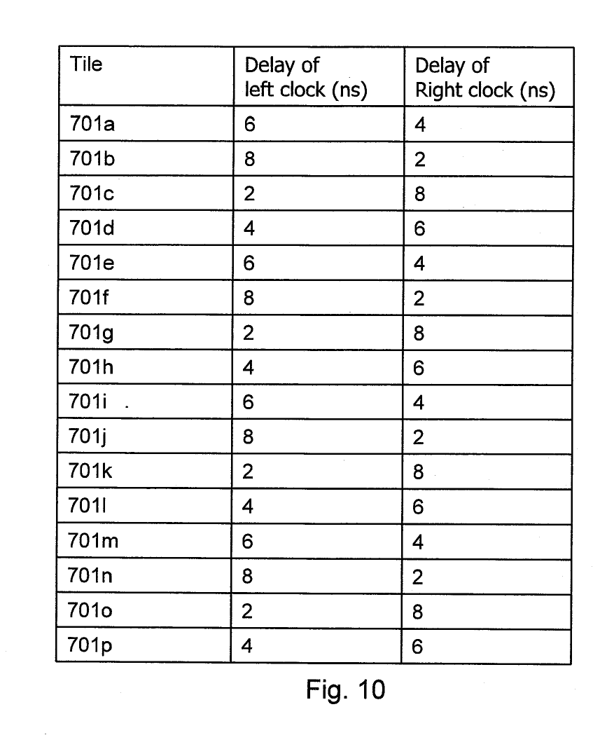

FIG. 10 shows a table of delays of the left clock signal and the right clock signal from the clock signal propagating in the external clock line 703a for each tile 701a-701p. As the internal clock distribution structure is created by putting together repeating tiles 701, the delay of the clock signal is predictable with a high degree of accuracy at each point of the array of the tiles 701. In the embodiment 2, the delay through a tile 701 is 2 ns in each internal clock line 901 and 902. Tiles 701 are characterized to give accurate 2 ns delays for each internal clock line 901 and 902. The delay can be adjusted by, for example, adding some delay elements, adjusting length of the internal clock lines, and so on. The delay of a certain tile is calculated by working out the number of tiles that the clock signal passes through and multiplying the number by the tile delay, 2 ns in the embodiment 2.

For example, the delay of the left clock signal and the right clock signal of the tile 701a is calculated as follows. The right clock signal of the tile 701a passes, from the external clock line 703a to the tile 701a, the tile 701b and 701a itself. In this embodiment 2 the tile itself for which the delay is calculated is included in the number of tiles that the clock signal passes through. The right clock signal of the tile 701a passes 2 tiles, so the delay of the right clock signal of the tile 701a is calculated by 2*2 (ns). Therefore, the delay of the right clock signal of the tile 701a is 4 ns, as shown in the FIG. 10. The left clock signal of the tile 701a passes, from the external clock line 703a to the tile 701a, the tile 701b, 701a itself, the external clock line 703b and 701a itself. The left clock signal of the tile 701 a passes 3 tiles, so the delay of the left clock signal of the tile 701a is calculated by 3*2(ns). Therefore, the delay of the left clock signal of the tile 701a is 6 ns, as shown in the FIG. 10. To the multiplexer 903 of the 701a, the right clock signal of the delay of 4 ns, and the left clock signal of the delay of 6 ns are input. The internal clock signal of the tile 701a is selected from the clock signal with 4 ns delay and the clock signal with 6 ns delay.

As described above, the PLD according to the embodiment 2 can provide clock signals with different delays to each tile 701a-701p without additional delay elements. As the clock signal is distributed by using internal clock lines, gaps between tiles for conventional clock trees are not required for all the tiles. Therefore, the area of the chip on which the PLD is fabricated is much conserved.

### Embodiment 3

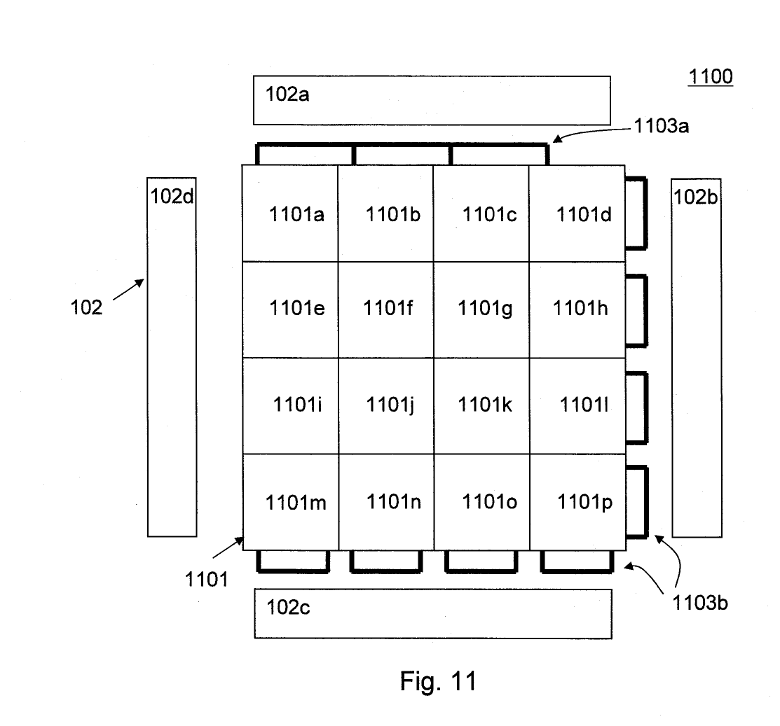

FIG. 11 illustrates simplified PLD architecture 1100 of embodiment 3 in plain view. The elements which are the same as that of the PLD 100 have the same numbers as that of the PLD 100 of the embodiment 1. The PLD 1100 includes an array of tiles 1101a-1101p, programmable I/O blocks 102a-102d, and external clock lines 1103a and 1103b. Some of the tiles 1101a-1101p and I/O blocks 102a-102d are connected by a number of connecting lines (not shown in the FIG. 11). The external clock line 1103a is connected to the tiles 1101a, 1101b, 1101c and 1101d. The external clock lines 1103b are connected to two ports of tiles 1101d, 1101h, 1101l, 1101m, 1101n, 1101o, and 1101p, respectively. A clock signal propagates in the external clock lines 1103a and 1103b. Conventional PLDs include a clock tree, such as the balanced tree (e.g. the H clock tree), and have external clock lines between the tiles, but the PLD of the embodiment 3 have no external clock lines between tiles which waste space of the PLD. Once the clock signal is provided into the tiles 1101, the clock signal propagates in internal clock lines of the tiles 1101, which will be explained. Structure of tile 1101, which is one of the tiles 1101a-1101p, other than elements related to clock propagation is as shown in the FIG. 2.

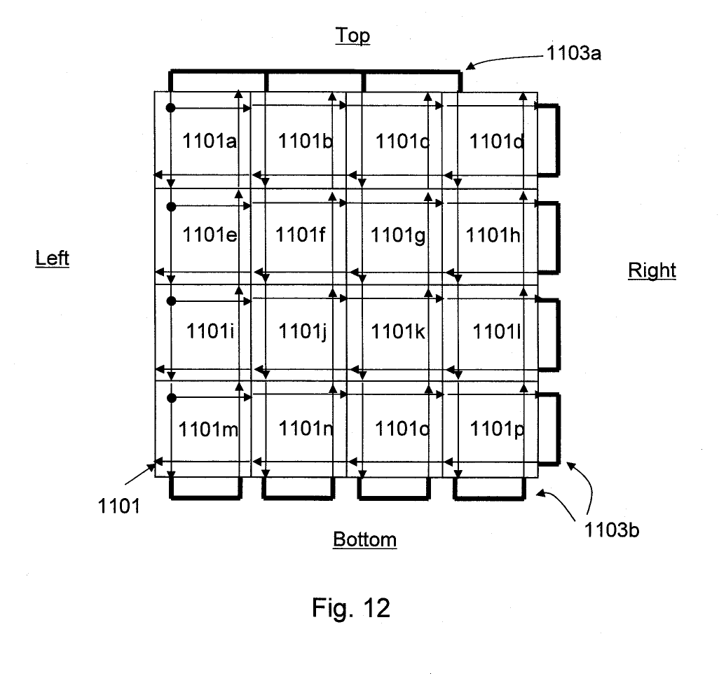

FIG. 12 shows schematic diagram of clock propagation of the PLD 1100. The clock signal is provided via the external clock line 1103a from a source of the clock signal (not shown) to the tiles 1101a, 1101b, 1101c, and 1101d, almost at the same time. In the embodiment 3, the external clock line 103a is adjusted so that the clock signal enters the tiles at substantially the same time from outside of the tiles. Possible ways to adjust the arrival time of the clock signal are, for example, to add capacitance to a particular line, to adjust length of a particular line, and so on. The clock signal propagates from top to bottom and from left to right of the array of the tiles 1101a-1101p. At the right edge of the tiles 1101d, 1101h, 1101l and 1101p, and at the bottom edge of the tiles 1101m-1101p, the clock signal once goes out of the tiles and comes back into the tiles respectively, via the external clock lines 1103b. The external clock lines 1103b are adjusted not to delay the clock signal by, for example, making length of the external clock lines 103b sufficiently short. When the clock signal propagates from the top to the bottom, the clock signal will be called a top clock signal, when the clock signal propagates from the bottom to the top, the clock signal will be called a bottom clock signal, when the clock signal propagates from the left to the right, the clock signal will be called a left clock signal, and when the clock signal propagates from the right to the left, the clock signal will be called a right clock signal.

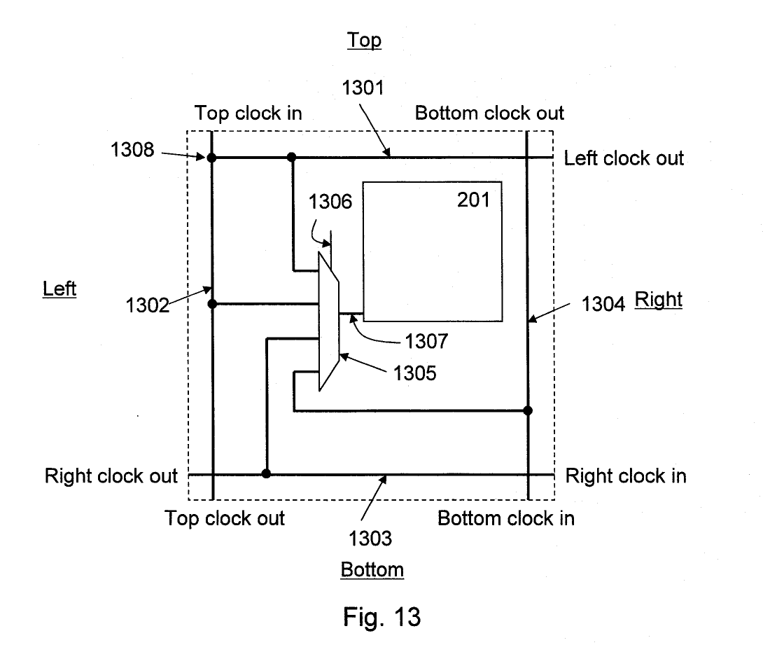

The structure of the tile 1101b, 1101c, 1101d, 1101f, 1101g, 1101h, 1101j, 1101k, 1101l, 1101n, 1101o, and 1101p, especially elements related to clock propagation, is as shown in FIG. 4. FIG. 13 shows simplified illustration of the tile 1101a, 1101e, 1101i and 1101m, especially elements related to clock propagation. The tile 1101a, 1101e, 1101i and 1101m comprises internal clock lines 1301, 1302, 1303 and 1304, a multiplexer 1305, a mux control line 1306, and a mux output line 1307. The clock signal propagates in the internal clock lines 1301, 1302, 1303 and 1304. The internal clock line 1301 is in the vicinity of top side of the tile 1101, the internal clock line 1302 is in the vicinity of left side of the tile 1101, the internal clock line 1303 is in the vicinity of bottom side of the tile 1101 and the internal clock line 1304 is in the vicinity of right side of the tile 1101. In this embodiment 3, the internal clock line 1301 and the internal clock line 1303 are substantially parallel, and the internal clock line 1302 and the internal clock line 1304 are substantially parallel. However, placement of the internal clock lines is not limited to this arrangement. The top clock signal propagates in the internal clock line 1302, from a top clock in on a top edge of the tile 1101a, 1101e, 1101i and 1101m to a top clock out on a bottom edge of the tile 1101a, 1101e, 1101i and 1101m, respectively. The bottom clock signal propagates in the internal clock line 1304 in the tile 1101a, 1101e, 1101i and 1101m, from a bottom clock in on a bottom edge of the tile 1101a, 1101e, 1101i and 1101m to a bottom clock out on a top edge of the tile 1101a, 1101e, 1101i and 1101m, respectively. The left clock signal propagates in the internal clock line 1301 in the tile 1101a, 1101e, 1101i and 1101m, from a node 1308 on the internal clock line 1302 of the tile 1101a, 1101e, 1101i and 1101m to a left clock out on a right edge of the tile 1101a, 1101e, 1101i and 1101m, respectively. The right clock signal propagates in the internal clock line 1303 in the tile 1101a, 1101e, 1101i and 1101m, from a right clock in on a right edge of the tile 1101a, 1101e, 1101i and 1101m to a right clock out on a left edge of the tile 1101a, 1101e, 1101i and 1101m, respectively.

The internal clock lines 1301, 1302, 1303 and 1304 are connected to input ports of the multiplexer 1305. The mux control line 1306 is connected to a control port of the multiplexer 1305. A mux control signal is provided to the multiplexer 1305 via the mux control line 1306. The output port of the multiplexer 1305 is connected to the mux output line 1307. The multiplexer 1305 selects one of the internal clock lines 1301, 1302, 1303 and 1304 according to the mux control signal of the mux control line 1306, and electrically connects the selected line to the mux output line 1307. Then the clock signal which propagates in the selected line propagates to the mux output line 1307. The mux output line 1307 is connected to the logic block 201, so the clock signal which propagates in the selected line propagates into the logic block 201 as an internal clock signal. Usually one of the internal clock lines 1301, 1302, 1303 and 1304 is selected at the time of mapping applications to the PLD, therefore the mux control signal is usually also determined at the time of mapping applications to the PLD by toolchains. The toolchains choose a suitable set of the internal clock lines for each tile by using information of timing analysis. Configuration memories store information of the mux control signal, and based on the information the mux control signal is generated in the tile and provided to the multiplexer 1305.

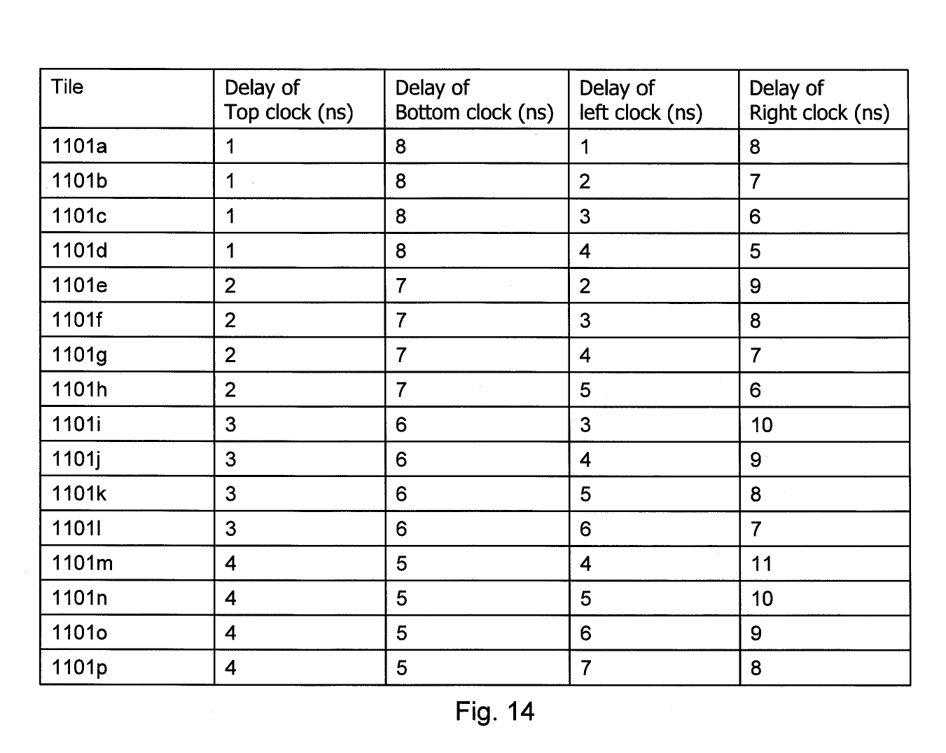

FIG. 14 shows a table of delays of the top clock signal, the bottom clock signal, the left clock signal and the right clock signal from the clock signal propagating in the external clock line 1103a for each tile 1101a-1101p. As the internal clock distribution structure is created by putting together repeating tiles 1101, the delay of the clock signal is predictable with a high degree of accuracy at each point of the array of the tiles 1101. In the embodiment 3, the delay through a tile 1101 is 1 ns in each internal clock line 1301, 1302, 1303 and 1304. The tiles 1301 are characterized to give accurate 1 ns delays for each internal clock line 1301, 1302, 1303 and 1304. The delay can be adjusted by, for example, adding some delay elements, adjusting length of the internal clock lines, and so on. The delay of a certain tile is calculated by working out the number of tiles that the clock signal passes through and multiplying the number by the tile delay, 1 ns in the embodiment 3.

For example, the delay of the top clock signal, the bottom clock signal, the left clock signal and the right clock signal of the tile 1101j is calculated as follows. The top clock signal of the tile 1101j passes, from the external clock line 1103a to the tile 1101j, the tile 1101b, 1101f and the tile 1101j itself. In this embodiment 3 the tile itself for which the delay is calculated is included in the number of tiles that the clock signal passes through. The top clock signal of the tile 1101j passes 3 tiles, so the delay of the top clock signal of the tile 1101j is calculated by 3*1 (ns). Therefore, the delay of the top clock signal of the tile 1101j is 3 ns, as shown in the FIG. 14. The bottom clock signal of the tile 1101j passes, from the external clock line 1103a to the tile 1101j, the tile 1101b, 1101f, 1101j itself, 1101n, 1101n, and 1101j itself. The bottom clock signal of the tile 1101j passes 6 tiles, so the delay of the bottom clock signal of the tile 1101j is calculated by 6*1 (ns). Therefore, the delay of the bottom clock signal of the tile 1101j is 6 ns, as shown in the FIG. 14. The left clock signal of the tile 1101j passes, from the external clock line 1103a to the tile 1101j, the tile 1101a, 1101e, 1101i and 1101j itself. The left clock signal of the tile 1101j passes 4 tiles, so the delay of the left clock signal of the tile 1101j is calculated by 4*1 (ns). Therefore, the delay of the left clock signal of the tile 1101j is 4 ns, as shown in the FIG. 14. The right clock signal of the tile 1101j passes, from the external clock line 1103a to the tile 1101j, the tile 1101a, 1101e, 1101i, 1101j itself, 1101k, 1101l, 1101l, 1101k, 1101j itself. The right clock signal of the tile 1101j passes 9 tiles, so the delay of the right clock signal of the tile 1101j is calculated by 9*1(ns). Therefore, the delay of the right clock signal of the tile 1101j is 9 ns, as shown in the FIG. 5. To the multiplexer 405 of the 1101j, the top clock signal with the delay of 3 ns, the bottom signal with the delay of 6 ns, the left clock signal of the delay of 4 ns, and the right clock signal of the delay of 9 ns are input. The internal clock signal of the tile 1101j is selected from the clock signal with 3 ns delay, the clock signal with 4 ns delay, the clock signal with 6 ns delay and the clock signal with 9 ns delay.

As described above, the PLD according to the embodiment 3 can provide clock signals with different delays to each tile 1101a-1101p without additional delay elements. As the clock signal is distributed by using internal clock lines, gaps between tiles for conventional clock trees are not required for all the tiles. Therefore, the area of the chip on which the PLD is fabricated is much conserved.

### Modification Example of Embodiment 3

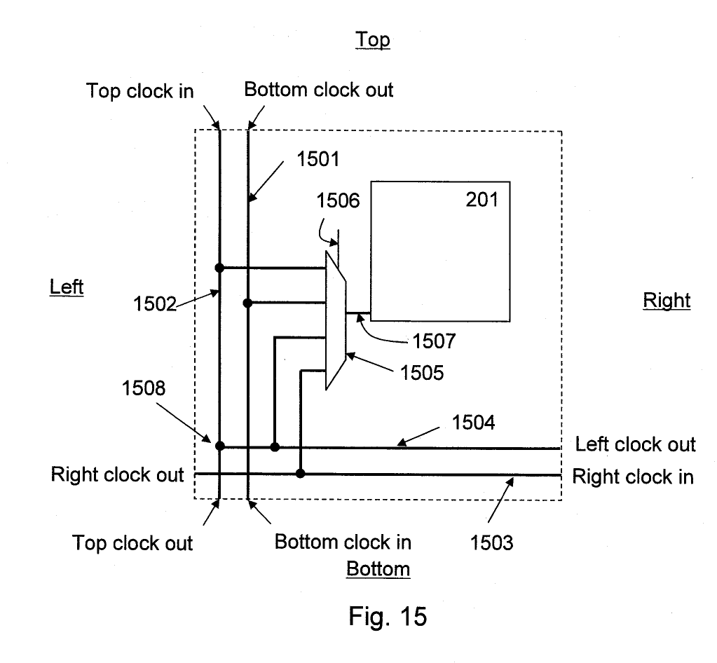

The modification example of embodiment 3 is different from the embodiment 3 in that the tile structure, especially elements related to clock propagation is as shown in FIG. 15.

FIG. 15 shows simplified illustration of the tile 1101a, 1101e, 1101i and 1101m, especially elements related to clock propagation. The tile 1101a, 1101e, 1101i and 1101m comprise internal clock lines 1501, 1502, 1503 and 1504, a multiplexer 1505, a mux control line 1506, and a mux output line 1507. The clock signal propagates in the internal clock lines 1501, 1502, 1503 and 1504. The internal clock line 1501 and 1502 are in the vicinity of the left side of the tile, and the internal clock line 1503 and 1504 are in the vicinity of the bottom side of the tile. The top clock signal propagates in the internal clock line 1502 in the tile 1101a, 1101e, 1101i and 1101m, from a top clock in on a top edge of the tile 1101a, 1101e, 1101i and 1101m to a top clock out on a bottom edge of the tile 1101a, 1101e, 1101i and 1101m, respectively. The bottom clock signal propagates in the internal clock line 1501 in the tile 1101a, 1101e, 1101i and 1101m, from a bottom clock in on a bottom edge of the tile 1101a, 1101e, 1101i and 1101m to a bottom clock out on a top edge of the tile 1101a, 1101e, 1101i and 1101m, respectively. The left clock signal propagates in the internal clock line 1504 in the tile 1101a, 1101e, 1101i and 1101m, from a node 1508 on the internal clock line 1502 of the tile 1101a, 1101e, 1101i and 1101m to a left clock out on a right edge of the tile 1101a, 1101e, 1101i and 1101m, respectively. The right clock signal propagates in the internal clock line 1503 in the tile 1101a, 1101e, 1101i and 1101m, from a right clock in on a right edge of the tile 1101a, 1101e, 1101i and 1101m to a right clock out on a left edge of the tile 1101a, 1101e, 1101i and 1101m, respectively.

The internal clock lines 1501, 1502, 1503 and 1504 are connected to input ports of the multiplexer 1505. The mux control line 1506 is connected to a control port of the multiplexer 1505. A mux control signal is provided to the multiplexer 1505 via the mux control line 1506. The output port of the multiplexer 1505 is connected to the mux output line 1507. The multiplexer 1505 selects one of the internal clock lines 1501, 1502, 1503, and 1504 according to the mux control signal of the mux control line 1506, and electrically connects the selected line to the mux output line 1507. Then the clock signal which propagates in the selected line propagates to the mux output line 1507. The mux output line 1507 is connected to the logic block 201, so the clock signal which propagates in the selected line propagates into the logic block 201 as an internal clock signal.

The internal clock lines 1501 and 1502 can be placed in the vicinity of right side of the tile if there is a space for them. The internal clock lines 1503 and 1504 can be placed in the vicinity of top side of the tile if there is a space for them.

### Embodiment 4

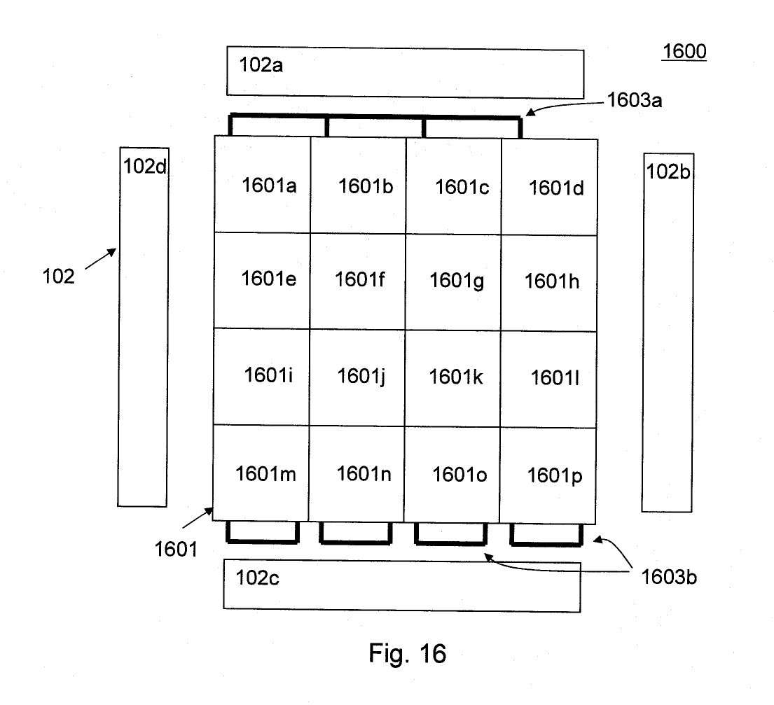

FIG. 16 illustrates simplified PLD architecture 1600 of embodiment 4 in plain view. The elements which are the same as that of the PLD 100 have the same numbers as that of the PLD 100 of the embodiment 1. The PLD 1600 includes an array of tiles 1601a-1601p, programmable I/O blocks 102a-102d, and external clock lines 1603a and 1603b. Some of the tiles 1601a-1601p and I/O blocks 102a-102d are connected by a number of connecting lines (not shown in the FIG. 16). The external clock line 1603a is connected to the tiles 1601a, 1601b, 1601c and 1601d. The external clock lines 1603b are connected to two ports of tiles 1101d, 1101h, 1101l, 1101m, 1101n, 1101o and 1101p, respectively. A clock signal propagates in the external clock lines 1603a and 1603b. Conventional PLDs include a clock tree, such as the balanced tree (e.g. the H clock tree), and have external clock lines between the tiles, but the PLD of the embodiment 4 have no external clock lines between tiles which waste space of the PLD. Once the clock signal is provided into the tiles 1601, the clock signal propagates in internal clock lines of the tiles 1601, which will be explained. Structure of tile 1601, which is one of the tiles 1601a-1601p, other than elements related to clock propagation is as shown in the FIG. 2.

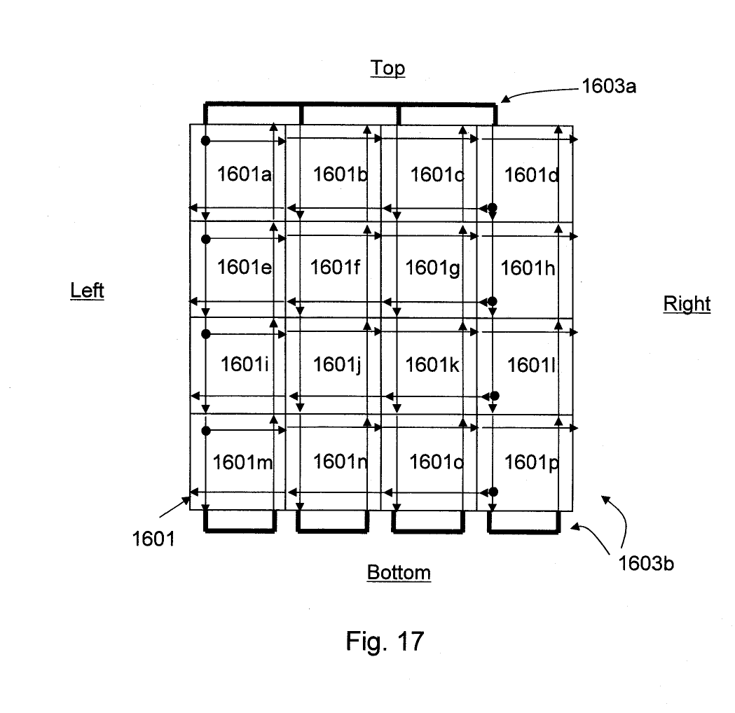

FIG. 17 shows schematic diagram of clock propagation of the PLD 1600. The clock signal is provided via the internal clock line 1603a from a source of the clock signal (not shown) to the tiles 1601a, 1601b, 1601c, and 1601d, almost at the same time. In the embodiment 4, the external clock line 103a is adjusted so that the clock signal enters the tiles at substantially the same time from outside of the tiles. Possible ways to adjust the arrival time of the clock signal are, for example, to add capacitance to a particular line, to adjust length of a particular line, and so on. The clock signal propagates from top to bottom, from left to right and from right to left of the array of the tiles 1601a-1601p. At the bottom edge of the tiles 1601m-1601p, the clock signal once goes out of the tiles and comes back into the tiles respectively, via the external clock lines 1603b. The external clock lines 103b are adjusted not to delay the clock signal by, for example, making length of the external clock lines 103b sufficiently short. When the clock signal propagates from the top to the bottom, the clock signal will be called a top clock signal, when the clock signal propagates from the bottom to the top, the clock signal will be called a bottom clock signal, when the clock signal propagates from the left to the right, the clock signal will be called a left clock signal, and when the clock signal propagates from the right to the left, the clock signal will be called a right clock signal.

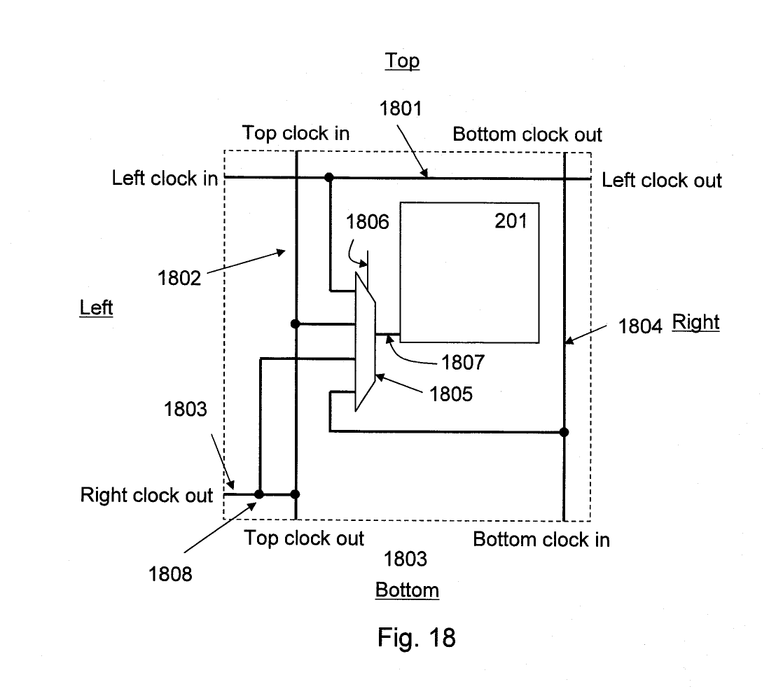

The structure of the tile 1601b, 1601c, 1601f, 1601g, 1601j, 1601k, 1601n, and 1601o, especially elements related to clock propagation, is as shown in the FIG. 4. The structure of the tile 1601a, 1601e, 1601i, and 1601m, especially elements related to clock propagation, is as shown in the FIG. 13. FIG. 18 shows simplified illustration of the tile 1601d, 1601h, 1601l and 1601p, especially elements related to clock propagation. The tile 1601d, 1601h, 1601l and 1601p comprises internal clock lines 1801, 1802, 1803 and 1804, a multiplexer 1805, a mux control line 1806, and a mux output line 1807. The clock signal propagates in the internal clock lines 1801, 1802, 1803 and 1804. The internal clock line 1801 is in the vicinity of top side of the tile, the internal clock line 1802 is in the vicinity of left side of the tile, the internal clock line 1803 is in the vicinity of bottom side of the tile and the internal clock line 1804 is in the vicinity of right side of the tile. In this embodiment 1, the internal clock line 401 and the internal clock line 403 are substantially parallel, and the internal clock line 402 and the internal clock line 404 are substantially parallel. However, placement of the internal clock lines is not limited to this arrangement. The top clock signal propagates in the internal clock line 1802, from a top clock in on a top edge of the tile 1601d, 1601h, 1601l and 1601p to a top clock out on a bottom edge of the tile 1601d, 1601h, 1601l and 1601p, respectively. The bottom clock signal propagates in the internal clock line 1804 in the tile 1601d, 1601h, 1601l and 1601p, from a bottom clock in on a bottom edge of the tile 1601d, 1601h, 1601l and 1601p to a bottom clock out on a top edge of the tile 1601d, 1601h, 1601l and 1601p, respectively. The left clock signal propagates in the internal clock line 1801 in the tile 1601d, 1601h, 1601l and 1601p, from a left clock in on a left edge of the tile 1101a, 1101e, 1101i and 1101m to a left clock out on a right edge of the tile 1101a, 1101e, 1101i and 1101m, respectively. The right clock signal propagates in the internal clock line 1803 in the tile 1101a, 1101e, 1101i and 1101m, from a node 1808 on the internal clock line 1802 of the tile 1101a, 1101e, 1101i and 1101m to a right clock out on a left edge of the tile 1101a, 1101e, 1101i and 1101m, respectively.

The internal clock lines 1801, 1802, 1803 and 1804 are connected to input ports of the multiplexer 1805. The mux control line 1806 is connected to a control port of the multiplexer 1805. A mux control signal is provided to the multiplexer 1805 via the mux control line 1806. The output port of the multiplexer 1805 is connected to the mux output line 1807. The multiplexer 1805 selects one of the internal clock lines 1801, 1802, 1803 and 1804 according to the mux control signal of the mux control line 1806, and electrically connects the selected line to the mux output line 1807. Then the clock signal which propagates in the selected line propagates to the mux output line 1807. The mux output line 1807 is connected to the logic block 201, so the clock signal which propagates in the selected line propagates into the logic block 201 as an internal clock signal. Usually one of the internal clock lines 1801, 1802, 1803 and 1804 is selected at the time of mapping applications to the PLD, therefore the mux control signal is usually also determined at the time of mapping applications to the PLD. The toolchains choose a suitable set of the internal clock lines for each tile by using information of timing analysis. Configuration memories store information of the mux control signal, and based on the information the mux control signal is generated in the tile and provided to the multiplexer 1805.

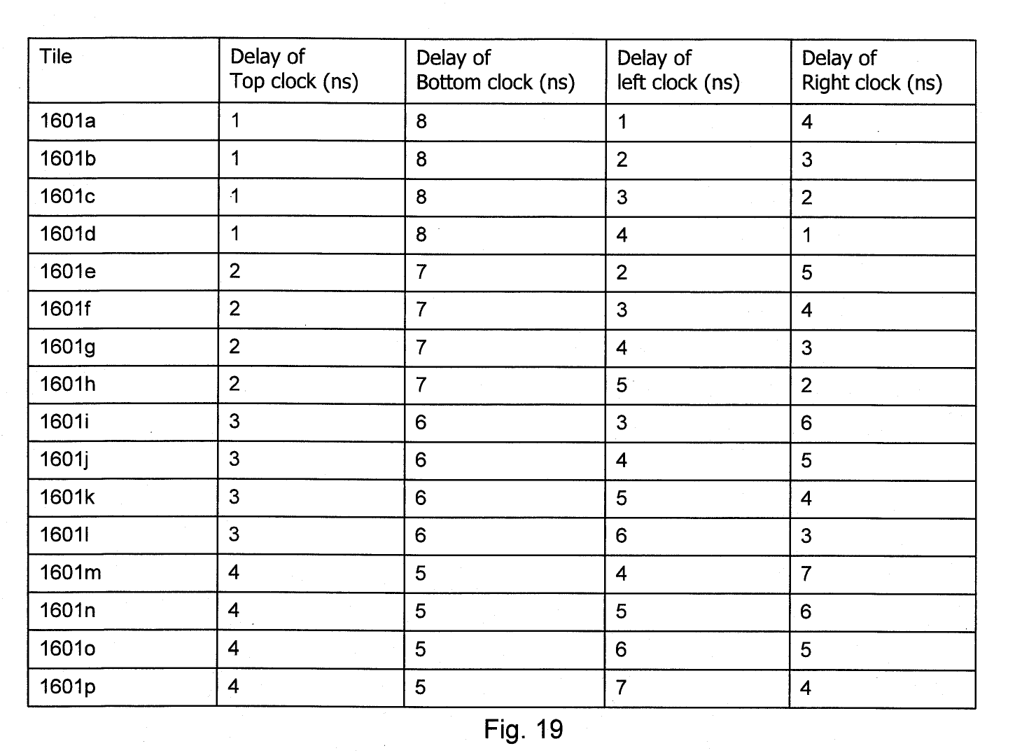

FIG. 19 shows a table of delays of the top clock signal, the bottom clock signal, the left clock signal and the right clock signal from the clock signal propagating in the external clock line 1603a for each tile 1601a-1601p. As the internal clock distribution structure is created by putting together repeating tiles 1601, the delay of the clock signal is predictable with a high degree of accuracy at each point of the array of the tiles 1601. In the embodiment 4, the delay through a tile 1601 is 1 ns in each internal clock line 1801, 1802, 1803 and 1804. The tiles 1601 are characterized to give accurate 1 ns delays for each internal clock line 1801, 1802, 1803 and 1804. The delay can be adjusted by, for example, adding some delay elements, adjusting length of the internal clock lines, and so on. The delay of a certain tile is calculated by working out the number of tiles that the clock signal passes through and multiplying the number by the tile delay, 1 ns in the embodiment 4.

For example, the delay of the top clock signal, the bottom clock signal, the left clock signal and the right clock signal of the tile 1601h is calculated as follows. The top clock signal of the tile 1601h passes, from the external clock line 1603a to the tile 1601h, the tile 1601d and 1601h itself. In this embodiment 4 the tile itself for which the delay is calculated is included in the number of tiles that the clock signal passes through. The top clock signal of the tile 1601h passes 2 tiles, so the delay of the top clock signal of the tile 1601h is calculated by 2*1 (ns). Therefore, the delay of the top clock signal of the tile 1601h is 2 ns, as shown in the FIG. 19. The bottom clock signal of the tile 1601h passes, from the external clock line 1603a to the tile 1601h, the tile 1601d, 1601h itself, 1601l, 1601p, 1601p, 1601l and 1601h itself. The bottom clock signal of the tile 1601h passes 7 tiles, so the delay of the bottom clock signal of the tile 1601h is calculated by 7*1 (ns). Therefore, the delay of the bottom clock signal of the tile 1601h is 7 ns, as shown in the FIG. 19. The left clock signal of the tile 1601h passes, from the external clock line 1603a to the tile 1601h, the tile 1601a, 1601e, 1601f, 1601g and 1601h itself. The left clock signal of the tile 1601h passes 5 tiles, so the delay of the left clock signal of the tile 1601h is calculated by 5*1 (ns). Therefore, the delay of the left clock signal of the tile 1601h is 5 ns, as shown in the FIG. 14. The right clock signal of the tile 1601h passes, from the external clock line 1603a to the tile 1601h, the tile 1601d and 1601h itself. The right clock signal of the tile 1601h passes 2 tiles, so the delay of the right clock signal of the tile 1601h is calculated by 2*1(ns). Therefore, the delay of the right clock signal of the tile 1601h is 2 ns, as shown in the FIG. 19. To the multiplexer 1805 of the 1601h, the top clock signal with the delay of 2 ns, the bottom signal with the delay of 7 ns, the left clock signal of the delay of 5 ns, and the right clock signal of the delay of 2 ns are input. The internal clock signal of the tile 1601h is selected from the clock signal with 2 ns delay, the clock signal with 5 ns delay, and the clock signal with 7 ns delay.

As described above, the PLD according to the embodiment 4 can provide clock signals with different delays to each tile 1601a-1601p without additional delay elements. As the clock signal is distributed by using internal clock lines, gaps between tiles for conventional clock trees are not required for all the tiles. Therefore, the area of the chip on which the PLD is fabricated is much conserved.

### Modification Example of Embodiment 4

The modification example of embodiment 4 is different from the embodiment 4 in that the tile structure, especially elements related to clock propagation is as shown in FIG. 18.

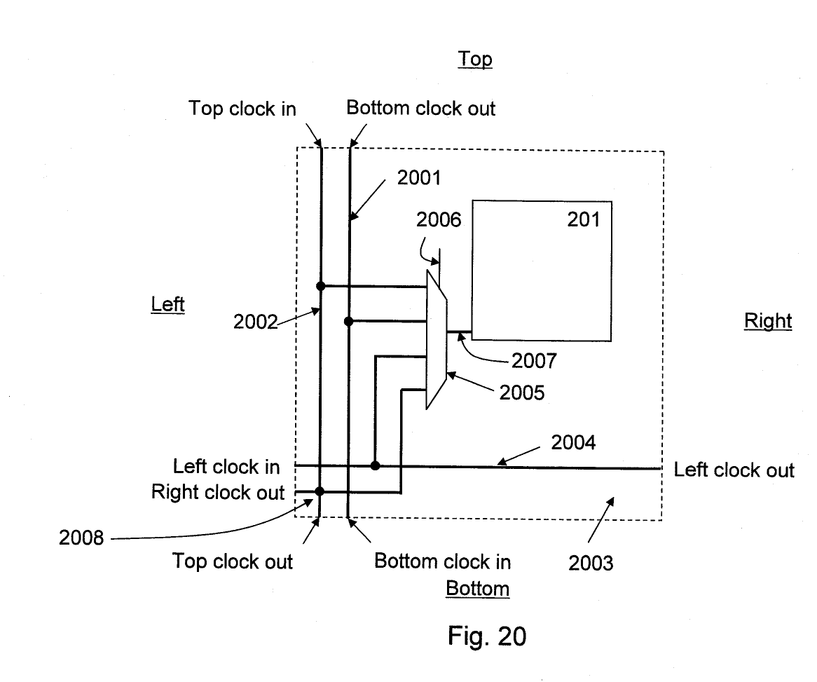

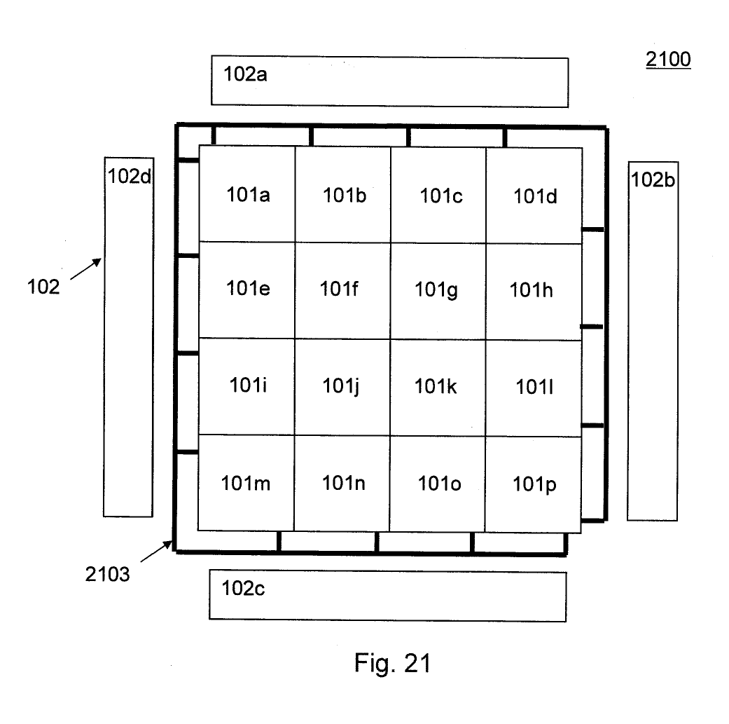

FIG. 20 shows simplified illustration of the tile 1601d, 1601h, 1601l and 1601p, especially elements related to clock propagation. The tile 1601d, 1601h, 1601l and 1601p comprise internal clock lines 2001, 2002, 2003 and 2004, a multiplexer 2005, a mux control line 2006, and a mux output line 2007. The clock signal propagates in the internal clock lines 2001, 2002, 2003 and 2004. The internal clock line 2001 and 2002 are in the vicinity of the left side of the tile, and the internal clock line 2003 and 2004 are in the vicinity of the bottom side of the tile. The top clock signal propagates in the internal clock line 2002 in the tile 1601d, 1601h, 1601l and 1601p, from a top clock in on a top edge of the tile 1601d, 1601h, 1601l and 1601p to a top clock out on a bottom edge of the tile 1601d, 1601h, 1601l and 1601p, respectively. The bottom clock signal propagates in the internal clock line 2001 in the tile 1601d, 1601h, 1601l and 1601p, from a bottom clock in on a bottom edge of the tile 1601d, 1601h, 1601l and 1601p to a bottom clock out on a top edge of the tile 1601d, 1601h, 1601l and 1601p, respectively. The left clock signal propagates in the internal clock line 2004 in the tile 1601d, 1601h, 1601l and 1601p, from a left clock in on a left edge of the tile 1601d, 1601h, 1601l and 1601p to a left clock out on a right edge of the tile 1601d, 1601h, 1601l and 1601p, respectively. The right clock signal propagates in the internal clock line 2003 in the tile 1601d, 1601h, 1601l and 1601p, from a node 2008 on the internal clock line 2002 of the tile 1601d, 1601h, 1601l and 1601p to a right clock out on a left edge of the tile 1601d, 1601h, 1601l and 1601p, respectively.

The internal clock lines 2001, 2002, 2003 and 2004 are connected to input ports of the multiplexer 2005. The mux control line 2006 is connected to a control port of the multiplexer 2005. A mux control signal is provided to the multiplexer 2005 via the mux control line 2006. The output port of the multiplexer 2005 is connected to the mux output line 2007. The multiplexer 2005 selects one of the internal clock lines 2001, 2002, 2003 and 2004 according to the mux control signal of the mux control line 2006, and electrically connects the selected line to the mux output line 2007. Then the clock signal which propagates in the selected line propagates to the mux output line 2007. The mux output line 2007 is connected to the logic block 201, so the clock signal which propagates in the selected line propagates into the logic block 201 as an internal clock signal.

The internal clock lines 2001 and 2002 can be placed in the vicinity of right side of the tile or in the middle of the tile if there is a space for them. The internal clock lines 2003 and 2004 can be placed in the vicinity of top side of the tile or in the middle of the tile if there is a space for them.

### Embodiment 5

FIG. 21 illustrates simplified PLD architecture 2100 of embodiment 5 of in plain view. The elements which are the same as that of the PLD 100 have the same numbers as that of the PLD 100 of the embodiment 1. The PLD 2100 includes an array of tiles 101a-101p, programmable I/O blocks 102a-102d, and external clock lines 2103. Some of the tiles 101a-101p and I/O blocks 102a-102d are connected by a number of connecting lines (not shown in the FIG. 21). The external clock line 2103 is connected to the tiles 101a, 101b, 101c, 101d, 101e, 101h, 101i, 101l, 101m, 101n, 101o, and 101p. A clock signal propagates in the external clock lines 2103. Conventional PLDs include a clock tree, such as the balanced tree (e.g. the H clock tree), and have external clock lines between the tiles, but the PLD of the embodiment 5 have no external clock lines between tiles which waste space of the PLD. Once the clock signal is provided into the tiles 101, the clock signal propagates in internal clock lines of the tiles 101. Structure of tile 101, which is one of the tiles 101a-101p is as shown in the FIG. 2.

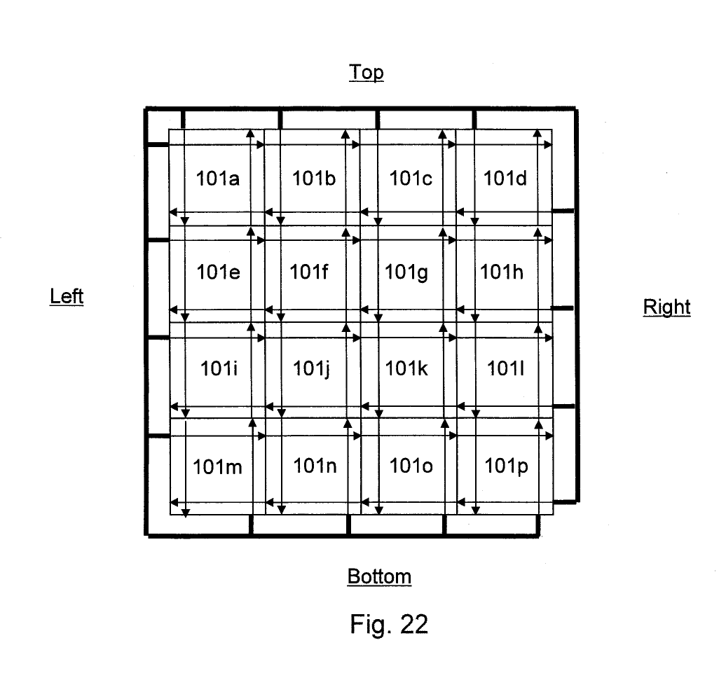

FIG. 22 shows schematic diagram of clock propagation of the PLD 2100. The clock signal is provided via the external clock line 2103 from a source of the clock signal (not shown) to the tiles 101a, 101b, 101c, 101d, 101e, 101h, 101i, 101l, 101m, 101n, 101o, and 101p, almost at the same time. In the embodiment 5, the external clock line 2103 is adjusted so that the clock signal enters the tiles at substantially the same time from outside of the tiles. Possible ways to adjust the arrival time of the clock signal are, for example, to add capacitance to a particular line, to adjust length of a particular line, and so on. The clock signal propagates from top to bottom, from bottom to top, from left to right and from right to left of the array of the tiles 101a-101p. When the clock signal propagates from the top to the bottom, the clock signal will be called a top clock signal, when the clock signal propagates from the bottom to the top, the clock signal will be called a bottom clock signal, when the clock signal propagates from the left to the right, the clock signal will be called a left clock signal, and when the clock signal propagates from the right to the left, the clock signal will be called a right clock signal.

The structure of the tiles 101a-101p, especially elements related to clock propagation, is as shown in the FIG. 4.

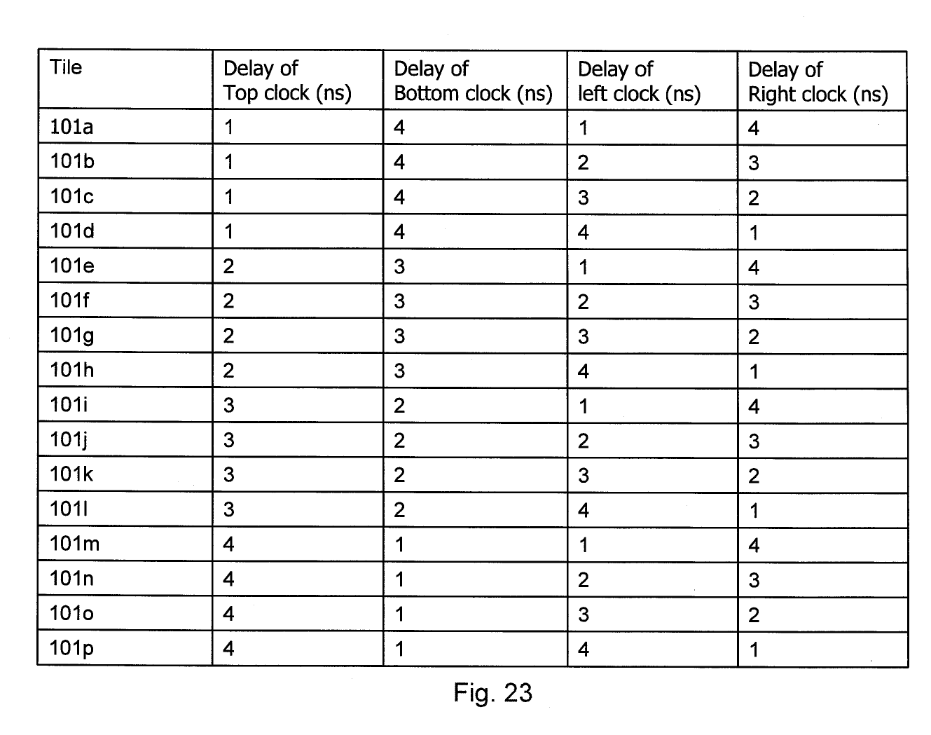

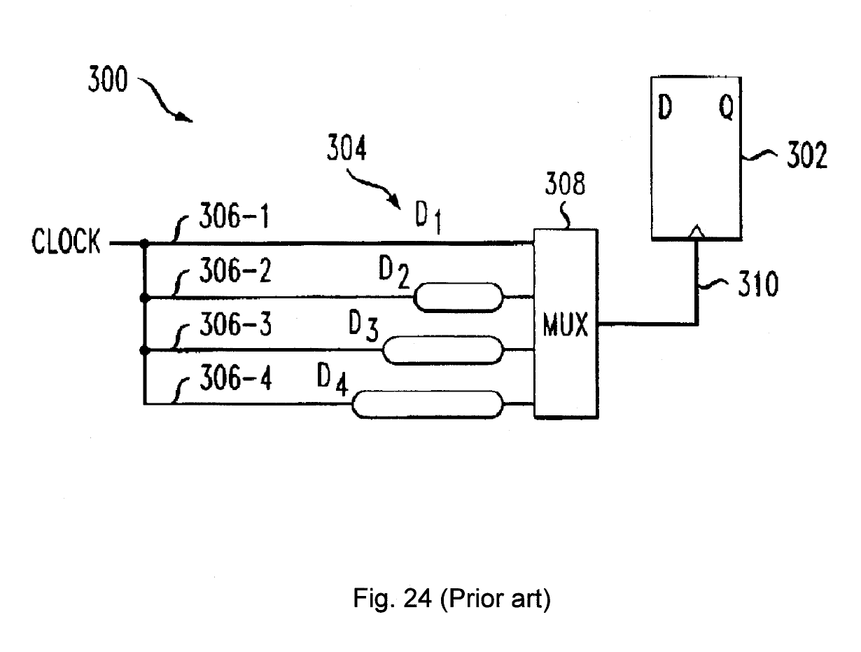

FIG. 23 shows a table of delays of the top clock signal, the bottom clock signal, the left clock signal and the right clock signal from the clock signal propagating in the external clock line 2103 for each tile 101a-101p. As the internal clock distribution structure is created by putting together repeating tiles 101, the delay of the clock signal is predictable with a high degree of accuracy at each point of the array of the tiles 101. In the embodiment 5, the delay through a tile 101 is 1 ns in each internal clock line 401, 402, 403 and 404. The tiles 101 are characterized to give accurate 1 ns delays for each internal clock line 401, 402, 403 and 404. The delay can be adjusted by, for example, adding some delay elements, adjusting length of the internal clock lines, and so on. The delay of a certain tile is calculated by working out the number of tiles that the clock signal passes through and multiplying the number by the tile delay, 1 ns in the embodiment 5.

For example, the delay of the top clock signal, the bottom clock signal, the left clock signal and the right clock signal of the tile 101n is calculated as follows. The top clock signal of the tile 101n passes, from the external clock line 2103 to the tile 101n, the tile 101b, 101f, 101j and the tile 101n itself. In this embodiment 5 the tile itself for which the delay is calculated is included in the number of tiles that the clock signal passes through. The top clock signal of the tile 101n passes 4 tiles, so the delay of the top clock signal of the tile 101n is calculated by 4*1 (ns). Therefore, the delay of the top clock signal of the tile 101n is 4 ns, as shown in the FIG. 23. The bottom clock signal of the tile 101n passes, from the external clock line 2103 to the tile 101n, the tile 101n itself. The bottom clock signal of the tile 101n passes 1 tiles, so the delay of the bottom clock signal of the tile 101n is calculated by 1*1 (ns). Therefore, the delay of the bottom clock signal of the tile 101n is 1 ns, as shown in the FIG. 23. The left clock signal of the tile 101n passes, from the external clock line 2103 to the tile 101n, the tile 101m, and 101n itself. The left clock signal of the tile 101n passes 2 tiles, so the delay of the left clock signal of the tile 101n is calculated by 2*1 (ns). Therefore, the delay of the left clock signal of the tile 101n is 2 ns, as shown in the FIG. 14. The right clock signal of the tile 101n passes, from the external clock line 2103 to the tile 101n, the tile 101p, 101o, and 101n itself. The right clock signal of the tile 101n passes 3 tiles, so the delay of the right clock signal of the tile 101n is calculated by 9*1(ns). Therefore, the delay of the right clock signal of the tile 101n is 3 ns, as shown in the FIG. 23. To the multiplexer 405 of the 101n, the top clock signal with the delay of 4 ns, the bottom signal with the delay of 1 ns, the left clock signal of the delay of 2 ns, and the right clock signal of the delay of 3 ns are input. The internal clock signal of the tile 101n is selected from the clock signal with 1 ns delay, the clock signal with 2 ns delay, the clock signal with 3 ns delay and the clock signal with 4 ns delay.

As described above, the PLD according to the embodiment 5 can provide clock signals with different delays to each tile 101a-101p without additional delay elements. As the clock signal is distributed by using internal clock lines, gaps between tiles of conventional clock trees are not required for all the tiles. Therefore, the area of the chip on which the PLD is fabricated is much conserved.

Therefore, the present disclosure generally concerns a programmable logic device 100, 700, 1100, 1600, 2100 including: a plurality of repeating units 101a, 101p; and an external clock line 103a, 103b for providing a clock signal to one or more of the plurality of repeating units. Each of the plurality of repeating units includes: a logic block 201 comprising logic circuits; and an internal clock line 401, 402, 403, 404 for receiving the clock signal from either the external clock line or an adjacent one of the plurality of repeating units and propagating the clock signal to another adjacent one of the plurality of repeating units or the external clock line.

Each of the plurality of repeating units can further include: a plurality of the internal clock lines 401, 402, 403, 404, each for respectively receiving the clock signal from either the external clock line or a different adjacent one of the plurality of repeating units and propagating the clock signal to another different adjacent one of the plurality of repeating units or the external clock line; and a selection unit such as the multiplexer 405 coupled to the plurality of internal clock lines and the logic block for selecting one of the plurality of internal clock lines. Each of the plurality of the internal clock lines propagates the clock signal with a different delay.

The plurality of repeating units can be arranged in a matrix configuration, wherein the one or more of the plurality of repeating units 101a, 101e, 101i, 101m receiving the clock signal from the external clock line are disposed in a column or row of the matrix configuration.

The external clock line can include a first portion 103a for sending the clock signal to a first group of the one or more of the plurality of repeating units 101a, 101e, 101i, 101m disposed in a first column or row of the matrix configuration and a second portion 103b for returning the clock signal to each of a second group of the one or more of the plurality of repeating units 101d, 101h, 101l, 101m, 101n, 101o, 101p disposed in a second column or row of the matrix configuration.

Although the invention has been described in conjunction with particular embodiments, it will be appreciated that various modifications and alternations may be made by those skilled in the art without departing from the spirit and scope of the invention.

### INDUSTRIAL APPLICABILITY

This invention can provide a more integrated circuit.

1. A programmable logic device comprising a plurality of first type repeating units, each of which includes interconnecting lines and a logic block comprising logic circuits, wherein the plurality of first type repeating units includes:
first, second and third repeating units, wherein the first repeating unit comprises a first clock line for propagating a clock signal with a first delay input from the third repeating unit and output to the second repeating unit.

2. The programmable logic device of claim 1, wherein
the first repeating unit is adjacent to the second repeating unit and the third repeating unit.

3. The programmable logic device of claim 1, wherein
the first repeating unit further comprises a second clock line for propagating the clock signal with a second delay, input from the second repeating unit and output to the third repeating unit.

4. The programmable logic device of claim 3, wherein
the first repeating unit further comprises a multiplexer,
the first clock line and the second clock line are connected to the multiplexer, and
the multiplexer outputs one of the clock signal with the first delay and the clock signal with the second delay to a logic block included in the first repeating unit.

5. The programmable logic device of claim 3, wherein
the first repeating unit, the second repeating unit and the third repeating unit are in a same column.

6. The programmable logic device of claim 3, wherein
the first clock line and the second clock line are substantially parallel.

7. The programmable logic device of claim 1, wherein
the first repeating unit further comprises a second clock line for propagating the clock signal with a second delay, input from a fourth repeating unit included in the plurality of first type repeating units and output to a fifth repeating unit included in the plurality of first type repeating units.

8. The programmable logic device of claim 7, wherein
the first repeating unit, the second repeating unit and the third repeating unit are in a same column,
the first repeating unit, the fourth repeating unit and the fifth repeating unit are in a same row.

9. The programmable logic device of claim 7, wherein
the first repeating unit further comprises a multiplexer,
the first clock line and the second clock line are connected to the multiplexer, and
the multiplexer outputs one of the clock signal with the first delay and the clock signal with the second delay to a logic block included in the first repeating unit.

10. The programmable logic device of claim 1 further comprises a plurality of second type repeating units, each of which includes interconnecting lines and a logic block comprising logic circuits, wherein
a fourth repeating unit, included in the plurality of second type repeating units, comprises a second clock line for propagating a clock signal with a second delay, input from a fifth repeating unit included in the plurality of second type repeating units and output to a sixth repeating unit included in the plurality of second type repeating units,
the first repeating unit, the second repeating unit and the third repeating unit are in a same column,
the fourth repeating unit and the fifth repeating unit are in a same column, and
the fourth repeating unit and the sixth repeating unit are in a same row.

11. A programmable logic device comprising:
a plurality of repeating units; and
an external clock line for providing a clock signal to one or more of the plurality of repeating units, wherein each of the plurality of repeating units includes:
a logic block comprising logic circuits;
an internal clock line for receiving the clock signal from either the external clock line or an adjacent one of the plurality of repeating units and propagating the clock signal to another adjacent one of the plurality of repeating units or the external clock line.

12. The programmable logic device of claim 11, wherein each of the plurality of repeating units further includes:
a plurality of the internal clock lines, each for respectively receiving the clock signal from either the external clock line or a different adjacent one of the plurality of repeating units and propagating the clock signal to another different adjacent one of the plurality of repeating units or the external clock line; and
a selection unit coupled to the plurality of internal clock lines and the logic block for selecting one of the plurality of internal clock lines.

13. The programmable logic device of claim 12, wherein each of the plurality of the internal clock lines propagate the clock signal with a different delay.

14. The programmable logic device of claim 11, wherein the plurality of repeating units are arranged in a matrix configuration, wherein the one or more of the plurality of repeating units receiving the clock signal from the external clock line are disposed in a column or row of the matrix configuration.

15. The programmable logic device of claim 11, wherein the plurality of repeating units are arranged in a matrix configuration, wherein the external clock line includes a first portion for sending the clock signal to a first group of the one or more of the plurality of repeating units disposed in a first column or row of the matrix configuration and a second portion for returning the clock signal to each of a second group of the one or more of the plurality of repeating units disposed in a second column or row of the matrix configuration.
